(19) United States
(12) Patent Application Publication
(10) Pub. No.: US 2026/0324225 A1
(43) Pub. Date: Oct. 15, 2026

(54) DISPLAY APPARATUS

(71) Applicant: LG Display Co., Ltd., Seoul (KR)

(72) Inventors: Minkyu Kim, Paju-si (KR); Hyunho Kim, Paju-si (KR)

(21) Appl. No.: 19/467,556

(22) Filed: Feb. 2, 2026

(30) Foreign Application Priority Data
Feb. 7, 2025 (KR) 10-2025-0015766

(51) Int. Cl. H10K 59/131; H10K 59/124; H10K 59/40

(52) U.S. Cl. CPC H10K 59/131; H10K 59/124; H10K 59/40

(57) ABSTRACT

A display apparatus includes a substrate including an active area and a non-active area disposed outside the active area, a link area, a bending area, and a pad area located in the non-active area, a first signal link wiring disposed in the link area, an organic insulating layer disposed on the first signal link wiring, a touch insulating structure disposed on the organic insulating layer, a second signal link wiring extending to the pad area along a surface of the touch insulating structure, and a plurality of pads disposed on the pad area. An end portion of the second signal link wiring overlaps the pad.

### CROSS REFERENCE TO RELATED APPLICATION

Pursuant to 35 U.S.C. § 119(a), the present application claims the benefit of an earlier filing date and right of priority to Korean Patent Application No. 10-2025-0015766, filed Feb. 7, 2025, the entire contents of which are incorporated herein for all purposes by this reference.

### TECHNICAL FIELD

This disclosure relates to a display apparatus.

### BACKGROUND

Display apparatuses are applied to various electronic devices such as TVs, smart phones, laptops, and tablets. To this end, a range of researches have been conducted to develop display apparatuses that are thinner, lighter, and have lower power consumption.

Examples of the display apparatus may include a liquid crystal display apparatus (LCD), a field light-emitting display apparatus (FED), an organic light emitting display apparatus (OLED), and the like.

A bezel area of the display apparatus may include an area surrounding an active area on a display panel of the display apparatus. The bezel area can protect the perimeter of the display panel and internal electronic components from external impact, pressure, or external damage. On the other hand, the bezel area is visually perceived by a user, so that it may become a factor reducing immersion into an image emitted from the active area.

Because of this, demand has been increasing for display apparatuses that implement a narrow bezel having a reduced bezel area where a screen of the display apparatus is not displayed, or a zero bezel having an effect of substantially eliminating the bezel area.

### SUMMARY

A display apparatus according to an implementation of the present disclosure may include a substrate including an active area and a non-active area disposed outside the active area, a link area, a bending area, and a pad area, which are located in the non-active area, a first signal link wiring disposed in the link area, an organic insulating layer disposed on the first signal link wiring, a touch insulating structure disposed on the organic insulating layer, a second signal link wiring extending to the pad area along a surface of the touch insulating structure, and a plurality of pads disposed on the pad area, wherein an end portion of the second signal link wiring may overlap with the pad.

According to an implementation of the present disclosure, by forming organic insulating films including a flat surface without a step difference on the non-active area extending in one side direction from the active area, it is possible to achieve the effect of preventing crack defects from occurring in wirings disposed in the link areas adjacent to the bending area of the non-active area.

According to an implementation of the present disclosure, by reinforcing the robustness of the area adjacent to the bending area in the non-active area of the substrate, it is possible to prevent a crack-prone point from occurring in the area extending from the active area by way of the bending area to the pad area.

Accordingly, it is possible to prevent that, during the bending operation of the bending area, the signal wiring is damaged by stress in the area adjacent to the bending area. Accordingly, there is an effect of being able to further reduce the bezel area visually perceived from the outside while reinforcing the robustness of the bending area and the area adjacent to the bending area.

According to the implementations of the present disclosure, the defect rate of the display apparatus due to damage in the signal wiring can be reduced, thereby contributing to the reduction of production energy, which would be required to produce additional display apparatuses, thereby having the effect of abating greenhouse gas emissions.

The present disclosure may have other effects besides the aforementioned ones, which are clearly recognizable to a person skilled in the art from the description below.

### BRIEF DESCRIPTION OF THE DRAWINGS

FIG. 1 is a plan view of an example of a display panel according to implementations of the present disclosure.

FIG. 2 is an example of a cross-sectional view taken along line I-I’ in FIG. 1.

FIG. 3 is an example of an enlarged plan view according to area II of FIG. 1.

FIGS. 4-6 are examples of views according to an implementation of the present disclosure.

FIGS. 7 and 8 are drawings according to an example of another implementation of the present disclosure.

FIG. 9 is a drawing according to an example of yet another implementation of the present disclosure.

### DETAILED DESCRIPTION

A display panel may include a bending area allowing its portion to be bent to hide the pad area beneath the active area. Thereby, it is possible to reduce the bezel area of the display apparatus visually perceived by a user.

The bending area includes a plurality of wirings for transmitting various signals to pixels on the active area, and the wirings may extend to the active area or the pad area through link areas adjacent to the bending area.

However, since the plurality of wirings are disposed on the bending area subjected to the bending and the link areas adjacent to the bending area, they may be vulnerable to defects such as cracks.

Implementations of the present disclosure can provide a display apparatus in which the wirings extending to the active area or the pad area by way of the link areas adjacent to the bending area may include a structure robust against cracks.

Some implementations of the present disclosure can provide a display device, in which it is possible to prevent that the wirings disposed in the link areas adjacent to the bending area are damaged.

Some implementations of the present disclosure can provide a display device, in which it is possible to simplify signal transmission paths of wirings extending to the active area or the pad area by way of the link areas adjacent to the bending area.

The objects to be accomplished according to an implementation of the present disclosure are not limited to the ones described above, and other objects and advantages of the present disclosure which are not mentioned can be understood from the following description, and will be more clearly understood from the implementations of the present disclosure. Furthermore, it will be readily appreciated that the objects and advantages of the present disclosure can be realized by the means presented in the claims, and combinations thereof.

Advantages and features of the present disclosure, and a method of achieving the advantages and features will become apparent when referring to the following implementations described later in detail together with the accompanying drawings. However, the present disclosure is not limited to the implementations as disclosed below, but may be embodied in various different forms. Thus, these implementations are set forth only to make the present disclosure complete, and to completely inform the scope of the present disclosure to those of ordinary skill in the technical field to which the present disclosure belongs.

A shape, a size, a ratio, an angle, a number, etc. disclosed in the drawings for illustrating implementations of the present disclosure are illustrative, and the present disclosure is not limited thereto. Throughout the detailed description, like reference symbols refer to like components. Further, in describing the present disclosure, if it is determined that a detailed description of a related known technology may unnecessarily obscure the gist of the present disclosure, the detailed description thereof will be omitted. When the terms "comprise", "include", "have", "be configured with", "be comprised of", and the like are used in the present disclosure, the presence or addition of other element may be allowable, unless the term “only” is used. When using an expression in a singular form to describe a component, it can include a meaning of a plural form unless explicitly stated to the contrary.

It should be noted that any component will be construed as including a tolerance or error range, even if there is no explicit description thereof.

In describing a position relationship between two elements, for example, when the position relationship is described using “on”, “above”, “below”, “next to”, and the like, one or more other elements may be interposed between the two elements unless “just”, “directly”, or "close" is used.

In describing a temporal relationship, for example, when the temporal order is described as “after”, “subsequent”, “next”, “before”, and the like, the case which is not continuous may also be included unless the term “just” or “directly” is used.

It will be understood that, although the terms “first”, “second”, etc. may be used herein to describe various elements, these elements should not be limited by these terms. These terms are merely used to distinguish one element from another element. So, a first element referred to in the following description may represent a second element, without departing from the scope of the technical idea of the present disclosure.

The individual features of the various implementations of the present disclosure may be coupled or combined with each other in part or in whole to be interconnected and operated in a variety of technical ways, and each implementation may be implemented independently of each other or implemented together in an associative relationship.

Hereinafter, a display apparatus according to each implementation of this disclosure will be described with reference to the accompanying drawings.

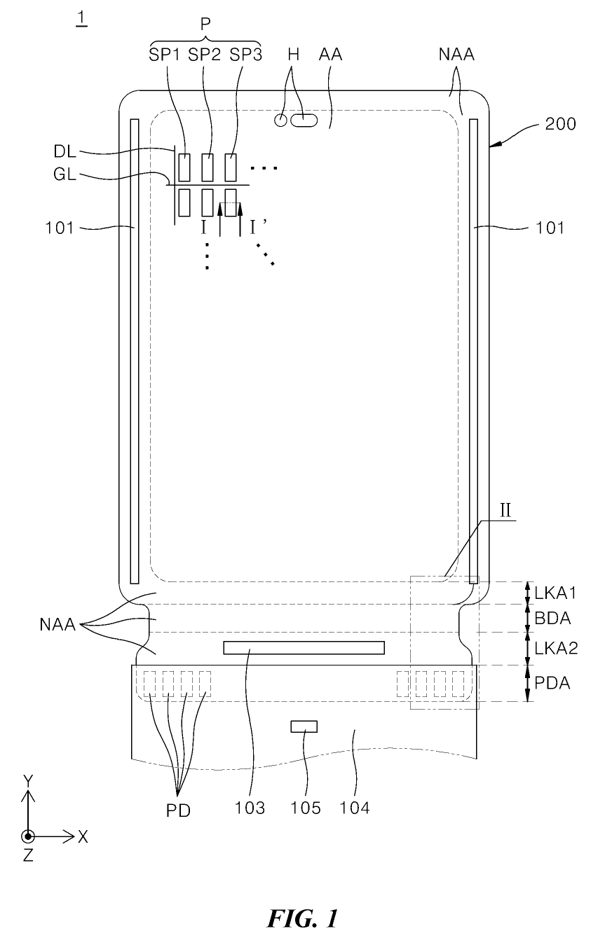

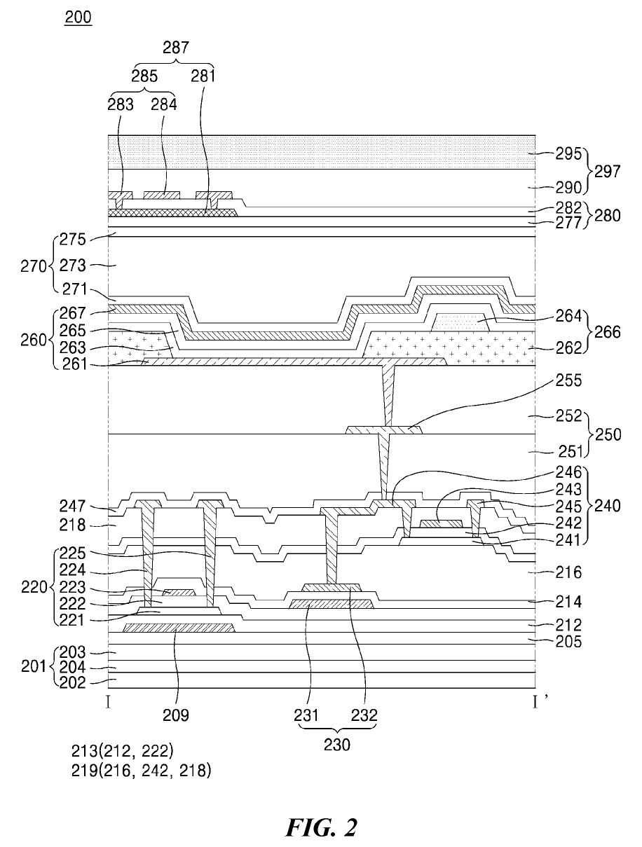

FIG. 1 is a plan view of a display panel according to implementations of the present disclosure. FIG. 2 is a cross-sectional view taken along line I-I’ in FIG. 1. FIG. 2 schematically shows one sub-pixel of the display device.

Referring to FIGS. 1 and 2, a display apparatus 1 according to an implementation of the present disclosure may include a display panel 200, a printed circuit board 104, and a control circuit chip 105, and the like.

The display panel 200 may include an active area AA (also referred to as a “display area”) and a non-active area NAA (also referred to as a “non-display area”). The active area AA, which is an area where images are displayed, may have a plurality of pixels P, data wirings DL, and gate wirings GL disposed therein. In one example, the active area AA may include a touch sensor unit disposed in a layer different from a layer in which the data wirings DL and the gate wirings GL are disposed. The non-active area NAA may be an area where no image is displayed. The non-active area NAA may be located in a peripheral area or border area of the display panel 200, although it is not limited thereto. For example, the remaining area on the active area AA other than a light-emitting area, through which light is emitted to the outside, may be referred to as the non-active area NAA. The non-active area NAA may define a bezel area of the display device. The bezel area may surround the outer side of the active area AA.

In the non-active area NAA, there may be disposed wirings for providing an electrical signal to the active area AA or for receiving an electrical signal from the active area AA. For example, in the non-active area NAA, there may be disposed driving circuits including a gate driving circuit, a data driving circuit, and a touch driving circuit. The non-active area NAA may include various drivers 101, 103 for driving the active area AA. For example, the drivers 101, 103 may include a first driver 101 and a second driver 103, although they are not limited thereto.

The first driver 101 may be disposed at the right and left edge portions of the non-active area NAA in a GIP (Gate In Panel) manner. The first driver 101 may transmit a gate signal onto the active area AA through the gate wirings GL. For example, the first driver 101 may be referred to as a gate driver. The second driver 103 may transmit a data signal onto the active area AA through a plurality of data wirings DL of the active area AA. Alternatively, it may sense a touch signal through a plurality of touch sensor units of the active area AA, transmit it to the control circuit chip 105, and transmit a signal provided from the control circuit chip 105 to the active area AA. For example, the second driver 103 may include a data driver or a touch driver, but it is not limited thereto.

The gate wirings GL may extend in a first direction X of the display panel 200, and the data wirings DL may intersect the gate wirings GL and extend in a second direction Y of the display panel 200.

The non-active area NAA extending in one direction of the active area AA may include a link area LKA1, LKA2, a bending area BDA, and a pad area PDA.

The link area LKA1, LKA2 may have signal wirings disposed therein for providing electrical signals to the active area AA or for receiving electrical signals from the active area AA. For example, the signal wirings may electrically connect the gate wirings GL, data wirings DL, or touch wirings in the active area AA with the second driver 103 or the control circuit chip 105. The signal wirings will be described later with reference to subsequent drawings.

The link area LKA1, LKA2 may include a first link area LKA1 and a second link area LKA2. The first link area LKA1 of the link area LKA1, LKA2 may be disposed between the active area AA and the pad area PDA, and the bending area BDA may be disposed between the first link area LKA1 and the pad area PDA. The second link area LKA2 may be disposed between the bending area BDA and the pad area PDA.

The bending area BDA may be bent, so that the printed circuit board 104 may be disposed to face the rear surface of the active area AA of the display panel 200. The printed circuit board 104 may include the control circuit chip 105. The control circuit chip 105 may control the first driver 101 and the second driver 103.

As the bending area BDA of the display panel 200 is bent, the pad area PDA of the non-active area NAA may be located under the active area AA. Thereby, the lower side non-active area perceived from the front of the display apparatus 1 can be reduced.

The active area AA may include a plurality of pixels P and holes H. The hole H may be an area in which an electronic component is disposed for adding various functions to the display apparatus 1. Examples of the electronic component may include a camera module for photographing or recording video in devices such as smartphones, laptops, and tablets, or various sensor devices for sensing an external object. The sensor device may include at least one of a proximity sensor, a gesture sensor, a color sensor, a biometric sensor, and an infrared sensor, although it is not limited thereto.

One pixel P may include a plurality of sub-pixels SP1, SP2, SP3. Through the plurality of sub-pixels SP1, SP2, SP3, an image may be displayed in the active area AA. The plurality of sub-pixels SP1, SP2, SP3 may be disposed in an array on the active area AA. In an example, a plurality of sub-pixels SP1, SP2, SP3 may be disposed to form a matrix type array while being spaced apart from each other in a first direction of the active area AA and a second direction intersecting with the first direction. The first direction may be a horizontal direction, an X-axis direction, or a row direction, while the second direction may be a vertical direction, a Y-axis direction, or a column direction. However, this is not exhaustive, and the arrangement shape, arrangement order, and arrangement direction of the sub-pixels SP1, SP2, SP3 may be changed in various ways.

This disclosure describes an implementation in which one pixel P is configured with the first sub-pixel SP1, the second sub-pixel SP2, and the third sub-pixel SP3; however, this is not exhaustive. For example, the one pixel P may further include additional sub-pixels.

The sub-pixels SP1, SP2, SP3 may each be implemented to emit light of the same color, such as white light, for every sub-pixel, or may each be implemented to emit light of different colors, such as red, green, or blue light, for every sub-pixel. For example, the first sub-pixel SP1 may implement red; the second sub-pixel SP2 may implement green; and the third sub-pixel SP3 may implement blue.

Referring to FIG. 2, the active area AA of the display panel 200 may include a pixel driving circuit including a plurality of transistors 220, 240 disposed on a substrate 201, a light-emitting element 260, and a touch sensor unit 287. In the present disclosure, for convenience of explanation, the configuration of one sub-pixel will be described, although it is not limited thereto.

One sub-pixel may include the light-emitting element 260 and the pixel driving circuit applying a driving current to the light-emitting element 260. The pixel driving circuit is disposed on the substrate 201, and the light-emitting element 260 is disposed on the pixel driving circuit. The pixel driving circuit may include the plurality of transistors 220, 240 and a storage capacitor 230. In one example, the plurality of transistors 220, 240 may include a first transistor 220 and a second transistor 240.

The substrate 201 may be a flexible plastic substrate. In the case where the substrate 201 is a plastic film, it may include multiple layers of insulating material. For example, the substrate 201 may include a first base layer 202, a second base layer 203, and a support layer 204. The first base layer 202 and the second base layer 203 may be disposed in upper and lower positions to be spaced apart from each other, and the support layer 204 may be disposed between them.

The first base layer 202 and the second base layer 203 may include an insulating material having flexibility. For example, the first base layer 202 and the second base layer 203 may include Polyimide (PI). The support layer 204 may support the first and second base layers 202, 203, which have relative flexibility. The support layer 204 may include an insulating material having rigidity relative to the first and second base layers 202, 203. For example, the support layer 204 may include silicon oxide (SiOx) or silicon nitride (SiNx).

On the substrate 201 a first buffer layer 205 may be disposed. The first buffer layer 205 may cover the surface of the substrate 201. The first buffer layer 205 may reduce or prevent penetration of moisture, oxygen, or impurities through the substrate 201. The first buffer layer 205 may be a single layer or multilayer made of an inorganic insulating material such as silicon oxide (SiOx) or silicon nitride (SiNx). The first buffer layer 205 may entirely cover the surface of the substrate 201 in the active area AA. For example, the first buffer layer 205 may extend to the non-active area NAA surrounding the outer side of the active area AA.

On the first buffer layer 205 a light blocking layer 209 may be disposed. The light blocking layer 209 may block external light incident on the transistor. For this purpose, the light blocking layer 209 may include an opaque metal material. On the light blocking layer 209 a second buffer layer 212 may be disposed. The second buffer layer 212 may protect the transistor from moisture, oxygen, or impurities. The second buffer layer 212 may be a single layer or multiple layers made of an inorganic insulating material such as silicon oxide (SiOx) or silicon nitride (SiNx), although it is not limited thereto. The second buffer layer 212 may entirely cover the surface of the substrate 201 in the active area AA. For example, the second buffer layer 212 may extend to the non-active area NAA surrounding the outer side of the active area AA.

On the second buffer layer 212 the first transistor 220 may be disposed. The first transistor 220 may include a first semiconductor layer 221, a first gate insulating layer 222, a first gate electrode 223, a first source electrode 224, and a first drain electrode 225. In one example, the first transistor 220 may be a switching transistor.

The first semiconductor layer 221 may include a channel area and source/drain areas. An area of the first semiconductor layer 221 overlapping with the first gate electrode 223 in the up and down direction may be the channel area. The source/drain areas may be respectively disposed on both sides of the channel area. The first semiconductor layer 221 may be formed from one or a combination of a polysilicon semiconductor layer and a low-temperature polysilicon semiconductor layer. In another example, the first semiconductor layer 221 may include an oxide semiconductor layer. For example, it may include at least one of oxide semiconductor materials, such as indium gallium zinc oxide (IGZO) or indium zinc oxide (IZO).

When the first semiconductor layer 221 includes an oxide semiconductor layer, the first transistor 220 may be an oxide thin film transistor. The first semiconductor layer 221 may be disposed to overlap with the light blocking layer 209 in the up and downward direction. The light blocking layer 209 may block external light incident on the first semiconductor layer 221.

Between the first semiconductor layer 221 and the first gate electrode 223, the first gate insulating layer 222 may be disposed. The first gate insulating layer 222 may extend outward while covering the first semiconductor layer 221. The first gate insulating layer 222 may be configured in a single layer or a plurality of layers of inorganic insulating material such as silicon oxide (SiOx) or silicon nitride (SiNx). The first gate insulating layer 222 may entirely cover the surface of the substrate 201 in the active area AA. For example, the first gate insulating layer 205 may extend to the non-active area NAA surrounding the outer side of the active area AA. In the non-active area NAA, the second buffer layer 212 and the first gate insulating layer 222 may be in contact with each other in upper and lower positions to form a first insulating structure 213.

The first gate electrode 223 may be disposed on the first gate insulating layer 222. On the first gate electrode 223 a first interlayer insulating layer 214 may be disposed. The first interlayer insulating layer 214 may be a single layer or multiple layers made of an inorganic insulating material such as silicon oxide (SiOx) or silicon nitride (SiNx). In one example, the first interlayer insulating layer 214 may extend to the non-active area NAA surrounding the outer side of the active area AA.

The first source electrode 224 and the first drain electrode 225 may be electrically connected to the first semiconductor layer 221.

The storage capacitor 230 may include a first storage electrode 231 and a second storage electrode 232. For example, the first storage electrode 231 may be located in the same layer as the first gate electrode 223. For example, the first storage electrode 231 may be disposed at a different position spaced apart from the first gate electrode 223 on the first gate insulating layer 222. The first storage electrode 231 may be made of the same material as the first gate electrode 223. The second storage electrode 232 may be disposed on the first interlayer insulating layer 214 so as to overlap with the first storage electrode 231 in the up and down direction.

The first storage electrode 231 and the second storage electrode 232 may be a single layer or multiple layers made of any one or an alloy of molybdenum (Mo), aluminum (Al), chromium (Cr), gold (Au), titanium (Ti), nickel (Ni), neodymium (Nd), and copper (Cu). However, these materials are not exhaustive.

On the second storage electrode 232 a second interlayer insulating layer 216 may be disposed. The second interlayer insulating layer 216 may be a single layer or multiple layers made of an inorganic insulating material such as silicon oxide (SiOx) or silicon nitride (SiNx). In one example, the second interlayer insulating layer 216 may extend to the non-active area NAA surrounding the outer side of the active area AA.

On the second interlayer insulating layer 216, the second transistor 240 may be disposed to be spaced apart from the first transistor 220. The second transistor 240 may be electrically connected with the first transistor 220. For example, the second transistor 240 may include a second semiconductor layer 241, a second gate insulating layer 242, a second gate electrode 243, a second source electrode 245, and a second drain electrode 246. In one example, the second transistor 240 may be a driving transistor electrically connected with the light-emitting element 260.

The second semiconductor layer 241 may include a channel area and source/drain areas. The area of the second semiconductor layer 241 which overlaps with the second gate electrode 243 in the up and down direction may be the channel area. The source/drain areas may be respectively disposed on both opposing sides of the channel area. The second semiconductor layer 241 may be configured in an oxide semiconductor layer. For example, it may include at least one of oxide semiconductor materials, such as indium gallium zinc oxide (IGZO) or indium zinc oxide (IZO). In one example, the second semiconductor layer 241 may be disposed to overlap with the storage capacitor 230 in the up and down direction. Thereby, the storage capacitor 230 can block external light incident on the second semiconductor layer 241 from the outside of the substrate 201. Therefore, it is possible to prevent the characteristics of the second transistor 240 from being changed by external light.

Between the second semiconductor layer 241 and the second gate electrode 243, the second gate insulating layer 242 may be disposed. The second gate insulating layer 242 may extend outward while covering the second semiconductor layer 241. For example, the second gate insulating layer 242 may extend to the non-active area NAA surrounding the outer side of the active area AA. The second gate insulating layer 242 may be configured in a single layer or a plurality of layers of inorganic insulating material such as silicon oxide (SiOx) or silicon nitride (SiNx).

The first gate electrode 223 or the second gate electrode 243 may be a single layer or multiple layers made of any one or an alloy of molybdenum (Mo), aluminum (Al), chromium (Cr), gold (Au), titanium (Ti), nickel (Ni), neodymium (Nd), and copper (Cu). However, these materials are not exhaustive.

A third interlayer insulating layer 218 may be disposed on the second gate electrode 243. The third interlayer insulating layer 218 may include an insulating material. For example, the third interlayer insulating layer 218 may be a single layer or multiple layers including inorganic insulating materials such as silicon oxide (SiOx), silicon nitride (SiNx), and silicon oxynitride (SiON). In one example, the third interlayer insulating layer 218 may extend to the non-active area NAA surrounding the outer side of the active area AA. In the non-active area NAA, the third interlayer insulating layer 218, the second gate insulating layer 242, and the second interlayer insulating layer 216 may be in contact with each other in the up-down direction to form a second insulating structure 219.

On the third interlayer insulating layer 218, the first source electrode 224, the first drain electrode 225, the second source electrode 245, and the second drain electrode 246 may be disposed.

The first source electrode 224 and the first drain electrode 225 may penetrate the third interlayer insulating layer 218, the second gate insulating layer 242, the second interlayer insulating layer 216, the first interlayer insulating layer 214, and the first gate insulating layer 222 to be in direct contact with and connected to the source/drain areas of the first semiconductor layer 221, respectively.

The second source electrode 245 and the second drain electrode 246 may penetrate the third interlayer insulating layer 218 and the second gate insulating layer 242 to be in direct contact with and connected to the source/drain areas of the second semiconductor layer 241, respectively. The second drain electrode 246 of the second transistor 240 may be electrically connected with the storage capacitor 230. For example, a portion of the second drain electrode 246 may penetrate the third interlayer insulating layer 218, the second gate insulating layer 242, and the second interlayer insulating layer 216 to be in direct contact with and connected to the second storage electrode 232 of the storage capacitor 230.

The first source electrode 224, the first drain electrode 225, the second source electrode 245, or the second drain electrode 246 may be a single layer or multiple layers made of any one or an alloy of molybdenum (Mo), aluminum (Al), chromium (Cr), gold (Au), titanium (Ti), nickel (Ni), neodymium (Nd), and copper (Cu), but is not limited thereto. In one example, the first source electrode 224 or the second drain electrode 225 may be a layer-stacking structure of titanium/aluminum/titanium (Ti/Al/Ti).

On the first source electrode 224, the first drain electrode 225, the second source electrode 245, or the second drain electrode 246, a passivation layer 247 may be disposed. The passivation layer 247 may be a single layer or multiple layers including an inorganic insulating material such as silicon oxide, silicon nitride, or silicon oxynitride. The passivation layer 247 may protect the pixel driving circuit disposed thereunder.

On the passivation layer 247 a planarization layer 250 may be disposed. The planarization layer 250 may planarize a step difference caused by the pixel driving circuit in the lower portion. The planarization layer 250 may include a multilayer structure of a first planarization layer 251 and a second planarization layer 252. For example, each of the first planarization layer 251 and the second planarization layer 252 may include an organic insulating material such as polyimide or acrylic resin. Accordingly, the planarization layer 250 may be referred to as an organic insulating layer. In one example, the first planarization layer 251 and the second planarization layer 252 may extend to the non-active area NAA surrounding the outer side of the active area AA.

On the first planarization layer 251 a pixel contact electrode 255 may be disposed. The pixel contact electrode 255 may penetrate the first planarization layer 251 and the passivation layer 247 to be in direct contact with the second drain electrode 246 of the second transistor 240.

On the planarization layer 250, the light-emitting element 260 may be formed. For example, on the second planarization layer 252, the light-emitting element 260 may be disposed. The light-emitting element 260 may include a first electrode 261, a light-emitting layer 263, a second electrode 265, and a capping layer 267.

The light-emitting element 260 may be electrically connected with the pixel driving circuit through the first electrode 261. For example, the first electrode 261 may penetrate the second planarization layer 252 to be in direct contact with the pixel contact electrode 255. Thereby, the first electrode 261 may be electrically connected to the second transistor 240 through the pixel contact electrode 255. However, FIG. 2 is for explaining one example of a method of supplying current to the first electrode 261, and it is not limited to the physical contact with the second transistor 240, which is the driving transistor, and the first electrode 261. In one example, a switching transistor electrically connected to the first electrode 261 may be a light-emitting transistor. For example, the light-emitting transistor may control the turn-on and turn-off states of the light-emitting element 260. The pixel contact electrode 255 may include a conductive material. For example, the pixel contact electrode 255 may include a metallic material such as aluminum (Al), chromium (Cr), copper (Cu), titanium (Ti), molybdenum (Mo), or tungsten (W). In one example, the pixel contact electrode 255 may have a multilayer structure of titanium/aluminum/titanium (Ti/Al/Ti).

The first electrode 261 may include a transparent conductive film. For example, the first electrode 261 may include indium-tin-oxide (ITO) or indium-zinc-oxide (IZO). Alternatively, the first electrode 261 may include a single-layer or multilayer structure including a reflective metal film formed from one or an alloy of silver (Ag), aluminum (Al), gold (Au), nickel (Ni), and chromium (Cr). The first electrode 261 may also be referred to as an anode electrode or pixel electrode.

On the first electrode 261 a bank 262 may be disposed. The bank 262 may be disposed so as to cover the edges of the first electrode 261. A portion of the bank 262 may extend to the second planarization layer 252. The upper surface of the first electrode 261 that is exposed without being covered by the bank 262 may become a light-emitting area. The bank 262 may be formed from an organic insulating material. The bank 262 may include, for example, photosensitive polyimide (PSPI), photoacrylic, or benzocyclobutene (BCB).

On the bank 262 a spacer 264 may be further disposed. The spacer 264 may be disposed to prevent damage to the bank 262 and the first electrode 261 during a process procedure. The spacer 264 may be formed from the same material as the bank 262. The bank 262 and the spacer 264 may be stacked in the up and down direction to form an organic insulating structure 266.

On the first electrode 261 a light-emitting layer 263 may be disposed. The light-emitting layer 263 may include a hole transport layer (HTL), an organic light-emitting layer (EML), an electron transport layer (ETL), a hole blocking layer (HBL), a hole injecting layer (HIL), an electron blocking layer (EBL), and an electron injecting layer (EIL). The light-emitting layer 263 may have a multi-stack structure in which two or more organic light-emitting layers (EMLs) are stacked.

On the light-emitting layer 263, the second electrode 265 may be disposed. The second electrode 265 may be commonly connected with the light-emitting layers 263 formed in all pixels. Therefore, the second electrode 265 may also be referred to as a cathode electrode or a common electrode. The second electrode 265 may include a semi-transparent conductive material. For example, it may be formed from a metal material such as magnesium (Mg), silver (Ag), or an alloy of silver (Ag) and magnesium (Mg) (Ag-Mg). In one example, the second electrode 265 may include a transparent conductive film of indium tin oxide (ITO), indium zinc oxide (IZO), or the like.

On the second electrode 265, the capping layer 267 may be disposed. The capping layer 267 may improve light extraction efficiency by preventing light generated from the light-emitting layer 263 from being lost.

On the light-emitting element 260 an encapsulation part 270 may be disposed. The encapsulation part 270 may protect the light-emitting element 260 from external oxygen or moisture. The encapsulation part 270 may extend to the non-active area NAA outside the active area AA while covering the active area AA.

The encapsulation part 270 may include a multilayer structure in which a first encapsulation layer 271, a second encapsulation layer 273, and a third encapsulation layer 275 are disposed. The second encapsulation layer 273 may be configured to be disposed between the first encapsulation layer 271 and the third encapsulation layer 275.

The first encapsulation layer 271 may be disposed on the capping layer 267. The second encapsulation layer 273 may be disposed on the first encapsulation layer 271. The second encapsulation layer 273 may cover the first encapsulation layer 271, and may have a sufficient thickness to have a flat surface. The second encapsulation layer 273 may prevent foreign substances from penetrating into the light-emitting element 260. On the second encapsulation layer 273, the third encapsulation layer 275 may be disposed. The first encapsulation layer 271 and the third encapsulation layer 275 may extend to the non-active area NAA surrounding the outer side of the active area AA. The first encapsulation layer 271 and the third encapsulation layer 275 extending to the non-active area NAA may be stacked in the up and down direction to form an inorganic insulating structure.

The first encapsulation layer 271 and the third encapsulation layer 275 may include an inorganic insulating material, and the second encapsulation layer 273 may include an organic insulating material. For example, each of the first encapsulation layer 271 and the third encapsulation layer 275 may include at least one material selected from silicon nitride (SiNx), silicon oxide (SiOx), or silicon oxynitride (SiON). The second encapsulation layer 273 may include at least one material selected from epoxy, polyimide, polyethylene, or acrylate.

On the encapsulation part 270 a touch part may be disposed. The touch part may include a touch buffer layer 277, the touch sensor unit 287, a touch interlayer insulating layer 282, a first touch protective layer 290, and a second touch protective layer 295.

The touch buffer layer 277 may be disposed on the third encapsulation layer 275. The touch buffer layer 277 may relieve stress between the encapsulation part 270 and the touch sensor unit 287 to prevent the encapsulation part 270 and the light-emitting element 260 from being damaged. The touch buffer layer 277 may include an inorganic insulating material. For example, the touch buffer layer 277 may include silicon nitride (SiNx).

The touch sensor unit 287 may include a plurality of touch electrodes 285 and a bridge electrode 281. The plurality of touch electrodes 285 and the bridge electrode 281 may be disposed on different layers. For example, the bridge electrode 281 may be disposed on the touch buffer layer 277. The plurality of touch electrodes 287 may be disposed on the touch interlayer insulating layer 282. The plurality of touch electrodes 287 may include a first touch electrode 283 and a second touch electrode 284. The bridge electrode 281 may electrically connect between adjacent first touch electrodes 283. For this, the first touch electrode 283 may penetrate the touch interlayer insulating layer 282 to be connected to the bridge electrode 281. The touch interlayer insulating layer 282 may include an inorganic insulating material. For example, the touch interlayer insulating layer 282 may include silicon nitride (SiNx).

The first touch electrode 283, the second touch electrode 284, or the bridge electrode 281 may include a conductive material. The first touch electrode 283, the second touch electrode 284, or the bridge electrode 281 may include a single layer or multiple layers made of any one or an alloy of molybdenum (Mo), aluminum (Al), chromium (Cr), gold (Au), titanium (Ti), nickel (Ni), neodymium (Nd), and copper (Cu).

The touch buffer layer 277 and the touch interlayer insulating layer 282 may extend toward the non-active area NAA. The touch buffer layer 277 and the touch interlayer insulating layer 282 in the non-active area NAA may be in contact with each other in the up and down direction to form a touch insulating structure 280.

On the touch sensor unit 287 a touch protective layer 297 may be disposed. The touch protective layer 297 may include the first touch protective layer 290 and the second touch protective layer 295. The first touch protective layer 290 may prevent damage to the touch sensor unit 287 caused by external impact and moisture. The first touch protective layer 290 may include an organic insulating material. For example, the first touch protective layer 290 may be made of a photosensitive acrylic-based or polyimide-based organic material. The first touch protective layer 290 may extend to the non-active area NAA.

On the first touch protective layer 290, the second touch protective layer 295 may be disposed. The second touch protective layer 295 may further protect the touch sensor unit 287 from external impact and moisture. Additionally, the second touch protective layer 295 may planarize a step difference caused by patterns constituting the touch sensor unit 287 therebelow. The second touch protective layer 295 may include an organic insulating material. For example, the second touch protective layer 295 may include the same organic insulating material as the first touch protective layer 290, although it is not limited thereto. For example, the second touch protective layer 295 may include an organic insulating material different from that of the first touch protective layer 290. For example, the touch protective layer 297 may extend to the non-active area NAA surrounding the outer side of the active area AA.

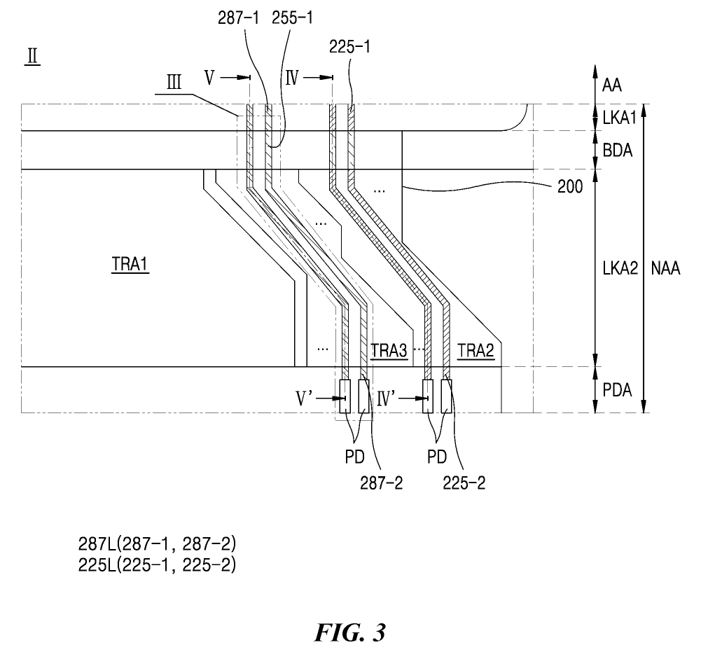

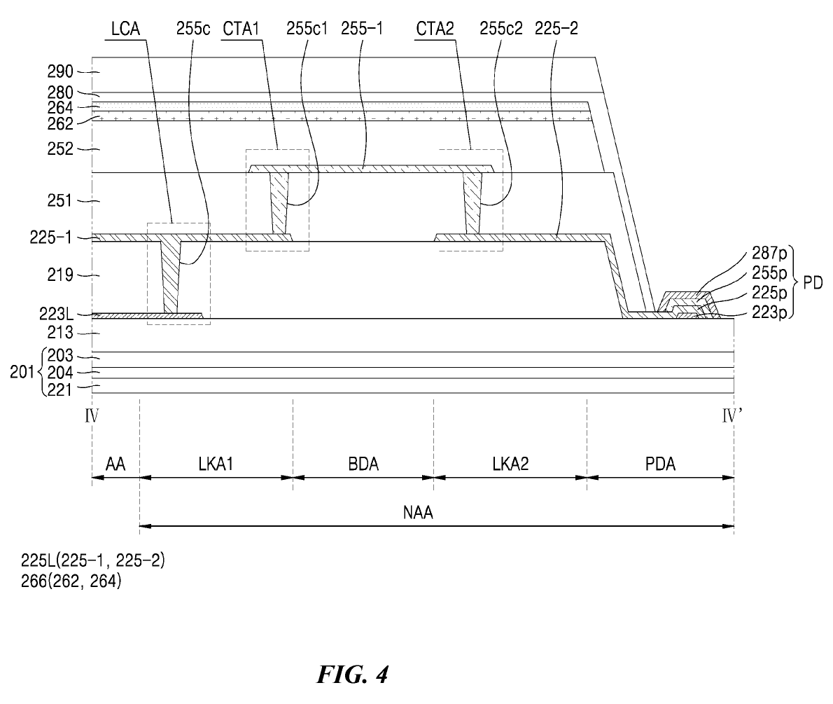

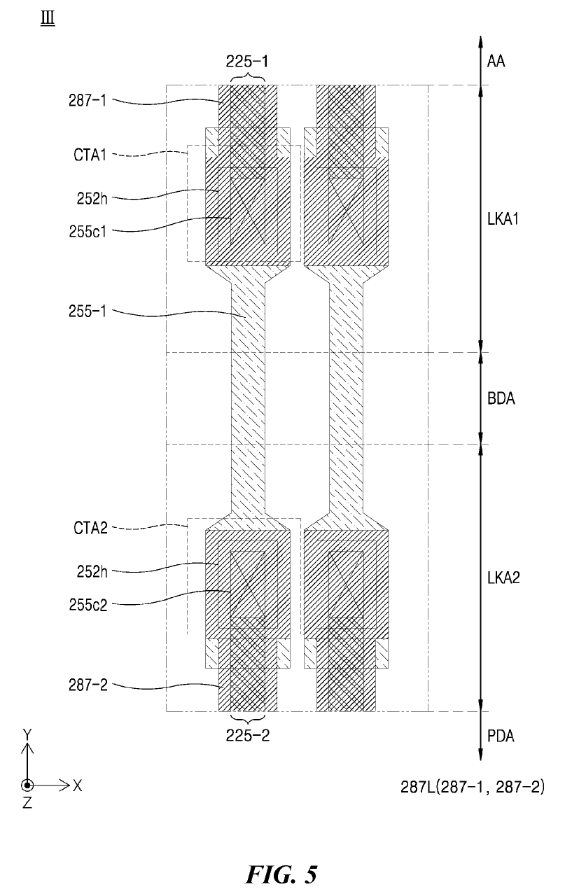

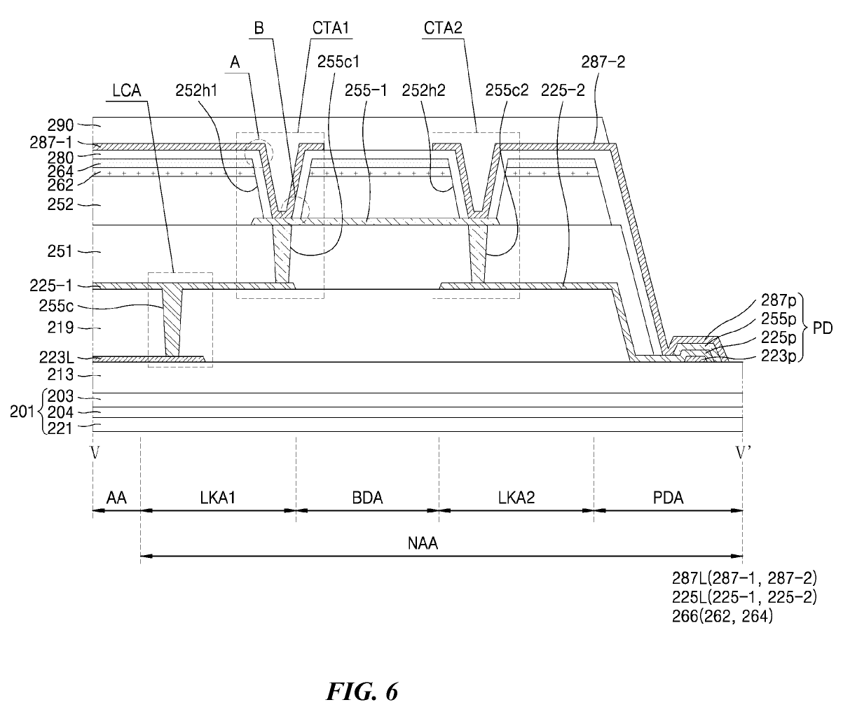

FIG. 3 is a view according to area II of FIG. 1. FIGS. 4-6 are views according to an implementation of the present disclosure. For example, FIG. 4 is a cross-sectional view taken along line IV-IV′ in FIG. 3. FIG. 5 is an enlarged plan view according to area III of FIG. 3. FIG. 6 is a cross-sectional view taken along line V-V′ in FIG. 3. FIG. 4 shows a portion of an area in which a first signal link wiring 223L is disposed to transmit a signal (or gate signal) for driving a pixel on the active area AA. FIGS. 5 and 6 respectively show a portion of an area in which a second signal link wiring 287L is disposed to transmit a signal to a touch sensor unit.

Referring to FIGS. 3-5, the display panel 200 may include the non-active area NAA disposed at one side edge portion of the active area AA. For example, it may include the first link area LKA1, the bending area BDA, the second link area LKA2, and a portion of the pad area PDA in the non-active area NAA. In one example, the second link area LKA2 may include a first area TRA1, a second area TRA2, and a third area TRA3.

The first area TRA1 may be an area in which the data wirings DL of the active area AA extend toward the pad area PDA. The second area TRA2 may be an area in which connection wirings 255-1 electrically connected with a plurality of first signal link wirings (223L, see FIG. 4) connected with the gate wirings GL extend toward the pad area PDA. In one example, the second area TRA2 may also be referred to as a GIP trace area. The third area TRA3 may be an area in which connection wirings 255-1 electrically connected with first portions 287-1 of a plurality of second signal link wirings (287L, see FIG. 6) connected with the touch electrodes (285, see FIG. 2) extend toward the pad area PDA. In one example, the third area TRA3 may also be referred to as a touch trace area. The third area TRA3 may be disposed between the first area TRA1 and the second area TRA2, although it is not limited thereto.

In the first link area LKA1, a first link contact electrode 225-1 connected to the second area TRA2 of the second link area LKA2 via the bending area BDA, and the first portion 287-1 of the second signal link wiring 287L connected to the third area TRA3 of the second link area LKA2 via the bending area BDA may be disposed at different positions from each other. In the second link area LKA2, a second link contact electrode 225-2 extending to the pad area PD, and the second portion 287-2 of the second signal link wiring 287L extending to the pad area PD may be disposed at different positions from each other. The bending area BDA may include a plurality of connection wirings 255-1. Each connection wiring 255-1 may electrically connect the signal wiring of the first link area LKA1 with the signal wiring of the second link area LKA2.

The plurality of first link contact electrodes 225-1 and the first portions 287-1 of the plurality of second signal link wirings 287L may each extend in the second direction (Y) in the first link area LKA1. The connection wiring 255-1 may extend in the second direction (Y) in the bending area BDA. The plurality of second link contact electrodes 225-2 and the second portions 287-2 of the plurality of second signal link wirings 287L may each extend in the second direction (Y) in the second link area LKA2. The second direction Y may be the perpendicular direction or vertical direction of the display panel 200.

Referring to FIGS. 3 and 4, on the first link area LKA1, the bending area BDA, the second link area LKA2, and the pad area PDA of the substrate 201, the first insulating structure 213 may be disposed. The first insulating structure 213 may include the second buffer layer 212 and the first gate insulating layer 222, which extend from the active area AA. For example, the first insulating structure 213 may include multiple layers including an inorganic insulating material.

On the first insulating structure 213, the plurality of first signal link wirings 223L may be disposed. The first signal link wirings 223L may be electrically connected to respective gate wirings GL of the active area AA. The first signal link wiring 223L may also be referred to as a gate link wiring. In one example, the first signal link wiring 223L may be formed from the same material as, and in the same process as, the first gate electrode 223.

On the first insulating structure 213 of the pad area PDA, a first pad pattern 223p may be disposed. The first pad pattern 223p may be formed from the same material as, and in the same process as, the first gate electrode 223.

On the first signal link wiring 223L, the second insulating structure 219 may be disposed. The second insulating structure 219 may be a structure formed such that the third interlayer insulating layer 218, the second gate insulating layer 242, and the second interlayer insulating layer 216, which extend from the active area AA, are in contact with each other in the up and down direction. For example, the second insulating structure 219 may include multiple layers including an inorganic insulating material.

The second insulating structure 219 may extend continuously to the first link area LKA1, the bending area BDA, and the second link area LKA2. The end portion of the second insulating structure 219 may be located in the pad area PDA. However, the first pad pattern 223p may not be covered by the second insulating structure 219.

In the implementation of the present disclosure, for convenience of explanation, the first signal link wiring 223L has been described, by way of example, as being formed in the same process as the first gate electrode 223, although it is not limited thereto. For example, the first signal link wiring 223L may be formed from the same material as, and in the same process as, the second storage electrode 232, or may be formed from the same material as, and in the same process as, the second gate electrode 243. Additionally, in another example, the first signal link wiring 223L may include a plurality of wirings disposed in different layers.

On the second insulating structure 219 a link contact electrode 225L may be disposed. The link contact electrode 225L may include a first link contact electrode 225-1 and a second link contact electrode 225-2. The first link contact electrode 225-1 may be disposed on the first link area LKA1 adjacent to the active area AA. The second link contact electrode 225-2 may be disposed on the second link area LKA2 adjacent to the pad area PDA. The first link contact electrode 225-1 and the second link contact electrode 225-2 may be disposed in the same layer to be spaced apart from each other. The first link contact electrode 225-1 and the second link contact electrode 225-2 may be formed from the same material as, and in the same process as, the second source electrode 245 and the second drain electrode 246.

The first link contact electrode 225-1 disposed on the first link area LKA1 may be electrically connected with the first signal link wiring 223L. For example, the first link contact electrode 225-1 may be connected with the first signal link wiring 223L through a first via electrode 225c penetrating the second insulating structure 219. In one example, the first via electrode 225c may be formed in one body with the first link contact electrode 225-1. An area in which the first link contact electrode 225-1 and the first signal link wiring 223L are electrically connected with each other may be a link contact area LCA.

The second link contact electrode 225-2, which is spaced apart from the first link contact electrode 225-1 to be disposed on the second link area LKA2, may extend to the pad area PDA. For example, the second link contact electrode 225-2 may extend along an inclined surface of the end portion of the second insulating structure 219 to cover the first pad pattern 223p on the pad area PDA. A portion of the second link contact electrode 225-2, which covers the first pad pattern 223p, may be a second pad pattern 225p.

On the second insulating structure 219, the first planarization layer 251 may be disposed to cover the first link contact electrode 225-1 and the second link contact electrode 225-2. The first planarization layer 251 may be disposed on the first link area LKA1, the bending area BDA, and the second link area LKA2 of the substrate 201. The first planarization layer 251 may extend to a portion of the pad area PDA. Thereby, it may cover the second link contact electrode 225-2 extending along the inclined surface of the end portion of the second insulating structure 219.

On the first planarization layer 251, the connection wiring 255-1 may be disposed. The connection wiring 255-1 may extend from the first link area LKA1 through the bending area BDA to the second link area LKA2. For example, the connection wiring 255-1 may include a first portion disposed on the first link area LKA1, a second portion disposed on the second link area LKA2, and a third portion located between the first portion and the second portion to be disposed on the bending area BDA.

The connection wiring 255-1 may be formed from the same material as, and in the same process as, the pixel contact electrode 255 of the active area AA. In one example, the connection wiring 255-1 may have a multilayer structure of titanium/aluminum/titanium (Ti/Al/Ti).

The first portion of the connection wiring 255-1 may be connected with the first link contact electrode 225-1 through a second via electrode 255c1 penetrating the first planarization layer 251 in a first contact area CTA1 which is an area in which the first portion of the connection wiring 255-1 and the first link contact electrode 225-1 are electrically connected with each other. Thereby, the first portion of the connection wiring 255-1 can be electrically connected with the first signal link wiring 223L through the second via electrode 255c1, the first link contact electrode 225-1, and the first via electrode 225c. In one example, the first link contact electrode 225-1 may be disposed in each first contact area CTA1, and adjacent first link contact electrodes 225-1 may be insulated from each other.

The second portion of the connection wiring 255-1 may be connected with the second link contact electrode 225-2 through a third via electrode 255c2 penetrating the first planarization layer 251 in a second contact area CTA2 which is an area in which the second portion of the connection wiring 255-1 and the second link contact electrode 225-2 are electrically connected with each other. Thereby, the second portion of the connection wiring 255-1 can be electrically connected with the second pad pattern 225p of the pad area PDA through the second link contact electrode 225-2. Consequently, the signal transmitted through the pad area PDA can be provided to a pixel on the active area AA through the second link contact electrode 225-2, the second contact area CTA2, the connection wiring 255-1, the first contact area CTA1, and the first link contact electrode 225-1, which serve as a signal transmission path. In one example, the second link contact electrode 225-2 may be disposed in each second contact area CTA2, and adjacent second link contact electrodes 225-2 may be insulated from each other.

On the second pad pattern 225p of the pad area PDA, a third pad pattern 255p may be disposed. The third pad pattern 255p may be formed from the same material as, and in the same process as, the pixel contact electrode 255. In one example, the third pad pattern 255p may have a multilayer structure of titanium/aluminum/titanium (Ti/Al/Ti).

On the connection wiring 255-1, the second planarization layer 252 may be disposed. The second planarization layer 252 may be disposed on the first link area LKA1, the bending area BDA, and the second link area LKA2 of the substrate 201, while covering the connection wiring 255-1. The second planarization layer 252 may planarize a step difference caused by the circuit element in the lower portion. The first planarization layer 251 and the second planarization layer 252 may include an organic insulating material.

On the second planarization layer 252, the organic insulating structure 266 may be disposed. The organic insulating structure 266 may be a configuration in which the bank 262 and the spacer 264 that extend from the active area AA are stacked in the up and down direction.

On the organic insulating structure 266, the touch insulating structure 280 may be disposed. The touch insulating structure 280 may be a structure in which the touch buffer layer 277 and the touch interlayer insulating layer 282 that extend from the active area AA are in contact with each other in the up and down direction. For example, the touch insulating structure 280 may include multiple layers including an inorganic insulating material. For example, the touch insulating structure 280 may include silicon nitride (SiNx).

The touch insulating structure 280 may cover an exposed surface of the organic insulating material disposed therebelow. For example, the touch insulating structure 280 may cover inclined surfaces of end portions of the organic insulating structure 266, the second planarization layer 252, and the first planarization layer 251. In one example, the touch insulating structure 280 may be disposed within the pad area PDA, although it is not limited thereto.

On the touch insulating structure 280, the first touch protective layer 290 may be disposed. The first touch protective layer 290 may include an organic insulating material.

On the third pad pattern 255p of the pad area PDA, a fourth pad pattern 287p may be disposed. The fourth pad pattern 287p may be formed from the same material as, and in the same process as, the touch electrode 285 or the bridge electrode 281 of the touch sensor unit 287. Thereby, in the pad area PDA, a pad PD may be disposed, in which the first pad pattern 223p, the second pad pattern 225p, the third pad pattern 255p, and the fourth pad pattern 287p are stacked from the lower side to the upper side. In the topmost portion of the pad PD, the fourth pad pattern 287p may be disposed to cover the lower structure without exposing it.

FIG. 5 is an enlarged plan view according to area III of FIG. 3. And FIG. 6 is a cross-sectional view taken along line V-V′ in FIG. 3. In FIGS. 5 and 6, components identical to those in FIGS. 3 and 4 may be denoted by the same reference signs. Thus, repetitive descriptions will be omitted or briefly made, and different features will be described.

Referring to FIGS. 5 and 6, the second signal link wiring 287L may be electrically connected with the first signal link wiring 223L through the connection wiring 255-1. For example, the second signal link wiring 287L may be formed from the same material as, and in the same process as, the touch electrode 285 extending from the active area AA.

The first signal link wiring 223L may be electrically connected with the first link contact electrode 225-1 through the first via electrode 255c in the link contact area LCA. The second link contact electrode 225-2 disposed to be spaced apart from the first link contact electrode 225-1 may extend to the pad area PDA to cover the first pad pattern 223p. The first link contact electrode 225-1 and the second link contact electrode 225-2 may be electrically connected to each other through the connection wiring 255-1. The connection wiring 255-1 may be covered with the second planarization layer 252.

The second planarization layer 252 may include a contact hole 252h1, 252h2. The contact hole 252h1, 252h2 may penetrate the organic insulating structure 266 and the second planarization layer 252 to expose a portion of the surface of the connection wiring 255-1. The contact hole 252h1, 252h2 may include a first contact hole 252h1 disposed on the first link area LKA1 and a second contact hole 252h2 disposed on the second link area LKA2.

The touch insulating structure 280 may be disposed on the organic insulating structure 266 and the second planarization layer 252, and in the first and second contact holes 252h1, 252h2, and may expose a portion of the surface of the connection wiring 255-1. The touch insulating structure 280 may cover the inclined surfaces of the end portions of the organic insulating structure 266, the second planarization layer 252, and the first planarization layer 251. In one example, the touch insulating structure 280 may be disposed within the pad area PDA, although it is not limited thereto.

The second signal link wiring 287L may be disposed on the touch insulating structure 280. For example, the first portion 287-1 of the second signal link wiring 287L may be disposed in the first contact area CTA1 of the first link area LKA1. The second portion 287-2 of the second signal link wiring 287L may be disposed in the second contact area CTA2 of the second link area LKA2 spaced apart from the first link area LKA1. The first portion 287-1 and the second portion 287-2 of the second signal link wiring 287L may be disposed in the same layer.

The first portion 287-1 of the second signal link wiring 287L may extend along the touch insulating structure 280 disposed on the first contact hole 252h1 to be in direct contact with the first portion of the connection wiring 255-1. Also, the second portion 287-2 of the second signal link wiring 287L may extend along the touch insulating structure 280 disposed on the second contact hole 252h2 to be in direct contact with the second portion of the connection wiring 255-1.

The second portion 287-2 of the second signal link wiring 287L may extend to the pad area PDA to cover the third pad pattern 255p. The portion of the second portion 287-2 of the second signal link wiring 287L, which extends to the pad area PDA, may become the fourth pad pattern 287p. Thereby, in the pad area PDA, a pad PD may be disposed, in which the first pad pattern 223p, the second pad pattern 225p, the third pad pattern 255p, and the fourth pad pattern 287p are stacked from the lower side to the upper side.

The second signal link wiring 287L may be covered with the first touch protective layer 290. The first touch protective layer 290 may cover the second signal link wiring 287L disposed on the active area AA, the first link area LKA1, the bending area BDA, and the second link area LKA2.

The second signal link wiring 287L may be in direct contact with the connection wiring 255-1 in each of the first and second contact areas CTA1, CTA2 of the link areas LKA1, LKA2 adjacent to the bending area BDA. Referring to FIG. 5, the first portion 287-1 of the second signal link wiring 287L may overlap with the first portion of the connection wiring 255-1 in the first contact area CTA1 in the up and down direction. Also, the second portion 287-1 of the second signal link wiring 287L may overlap with the second portion of the connection wiring 255-1 in the second contact area CTA2 in the up and down direction.

Thereby, the signal transmitted through the pad PD can be provided to the active area AA through the second portion 287-1 of the second signal link wiring 287L, the connection wiring 255-1, and the first portion 287-1 of the second signal link wiring 287L, which serve as a signal transmission path.

On the second signal link wiring 287L, the first touch protective layer 290 may be disposed.

Referring to FIG. 6, the first and second contact holes 252h1, 252h2 disposed in the first and second contact areas CTA1, CTA2 may be formed by removing the second planarization layer 252. During the process of forming the first and second contact holes 252h1, 252h2, a step difference may be generated on the second planarization layer 252 in an area A corresponding to the upper edge portion of the first and second contact holes 252h1, 252h2. Additionally, during the process of exposing a portion of the surface of the connection wiring 255-1 in the first and second contact holes 252h1, 252h2, a step difference may be generated by the touch insulation structure 280 in an area B corresponding to the bottom surface of the first and second contact holes 252h1, 252h2.

The second signal link wiring 287L may be formed along the shapes of the step difference generated on the second planarization layer 252 and the step difference generated on the touch insulation structure 280. A portion where the step difference has been generated may become a weak point where the second signal link wiring 287L is damaged, so that a crack defect may occur. When a physical impact or the like is applied to the display device, the second signal link wiring 287L at the portion where the crack has been generated may be disconnected. As a result, since a signal cannot be transmitted to the active area AA, pixel defects or operation defects occur, and thus the defect rate of the display apparatus may increase.

Accordingly, another implementation of the present disclosure may includ a structure capable of preventing the generation of a weak point that causes a crack in the second signal link wiring 287L.

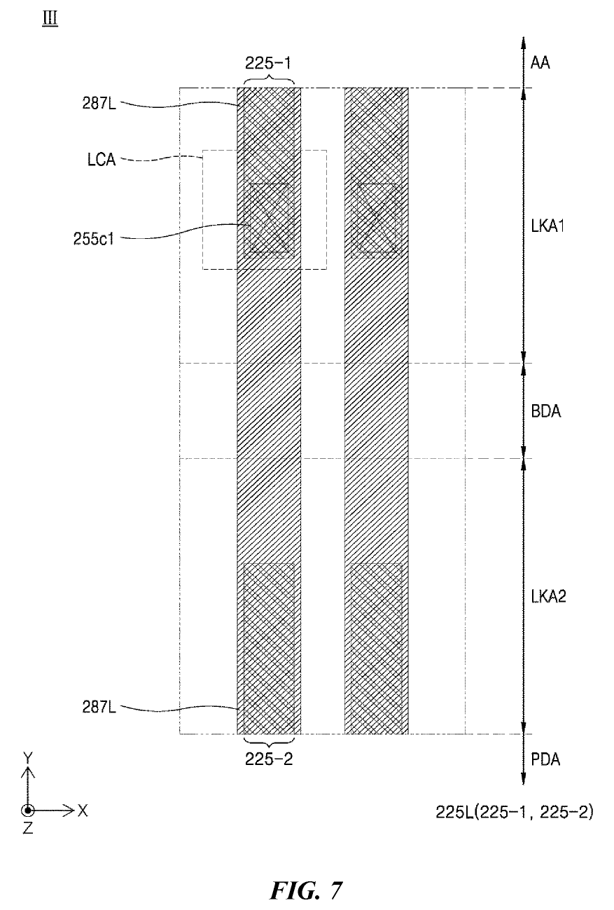

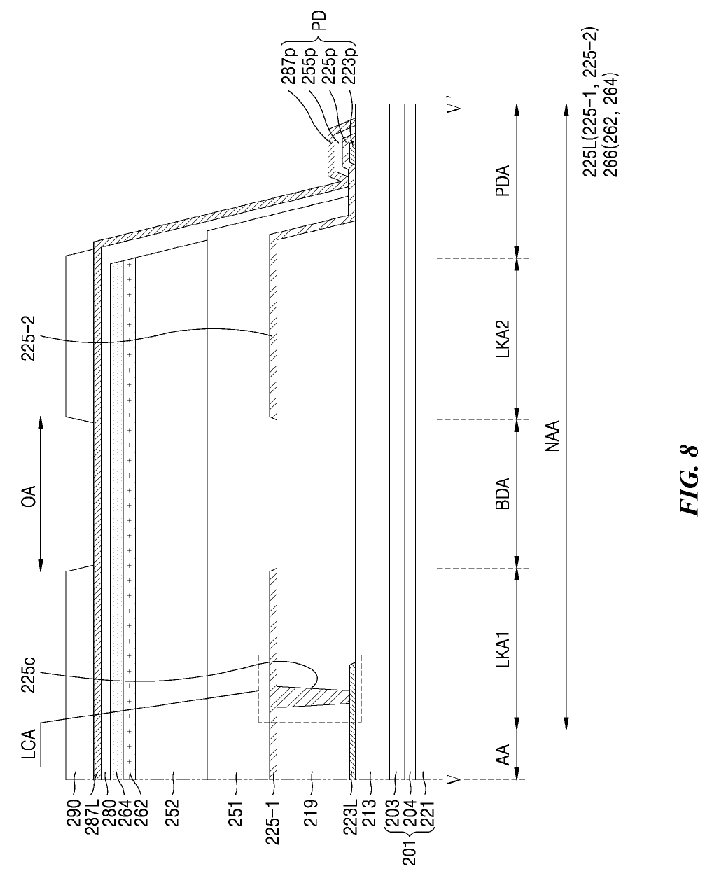

FIGS. 7 and 8 are drawings according to another implementation of the present disclosure. For example, FIG. 7 is an enlarged plan view according to area III of FIG. 3. FIG. 8 is a cross-sectional view taken along line V-V′ in FIG. 3. FIGS. 7 and 8 show a portion of an area in which a second signal link wiring is disposed for transmitting a signal to a touch sensor unit. In FIGS. 7 and 8, components identical to those in FIGS. 4-6 may be denoted by the same reference sings. Thus, repetitive descriptions will be omitted or briefly made, and different features will be described.

Referring to FIGS. 7 and 8, on the non-active area NAA of the substrate 201, the first insulating structure 213 may be disposed. On the first insulating structure 213, the first signal link wiring 223L may be disposed. On the first insulating structure 213 of the pad area PDA, a first pad pattern 223p may be disposed. The first pad pattern 223p may be formed from the same material as, and in the same process as, the first signal link wiring 223L and the first gate electrode 223.

On the first signal link wiring 223L, the second insulating structure 219 may be disposed. The second insulating structure 219 may include multiple layers including an inorganic insulating material. For example, the second insulating structure 219 may be a structure formed such that the third interlayer insulating layer 218, the second gate insulating layer 242, and the second interlayer insulating layer 216, which extend from the active area AA, are in contact with each other in the up and down direction.

On the second insulating structure 219 a link contact electrode 225L may be disposed. The link contact electrode 225L may include a first link contact electrode 225-1 and a second link contact electrode 225-2. The first link contact electrode 225-1 and the second link contact electrode 225-2 may be disposed in the same layer. The first link contact electrode 225-1 and the second link contact electrode 225-2 may be disposed to be spaced apart from each other. For example, the first link contact electrode 225-1 may be disposed on the first link area LKA1 adjacent to the active area AA. The second link contact electrode 225-2 may be disposed on the second link area LKA2 adjacent to the pad area PDA. The first link contact electrode 225-1 and the second link contact electrode 225-2 may be formed from the same material as, and in the same process as, the second source electrode 245 and the second drain electrode 246.

The first link contact electrode 225-1 disposed on the first link area LKA1 may be electrically connected with the first signal link wiring 223L through the first via electrode 225c. The first signal link wiring 223L may be electrically connected with the first link contact electrode 225-1 through the first via electrode 255c in the link contact area LCA.

The second link contact electrode 225-2 disposed on the second link area LKA2 may extend to the pad area PDA to be in contact with the first pad pattern 223p.

On the first link contact electrode 225-1 and the second link contact electrode 225-2, the first planarization layer 251 may be disposed. The first planarization layer 251 may extend to a portion of the pad area PDA. Thereby, it may cover the second link contact electrode 225-2 extending along the inclined surface of the end portion of the second insulating structure 219.

The first planarization layer 251 may planarize a step difference caused by the first link contact electrode 225-1 and the second link contact electrode 225-2.

On the first planarization layer 251, the second planarization layer 252 may be disposed. The second planarization layer 252 may be disposed on the first link area LKA1, the bending area BDA, and the second link area LKA2 of the substrate 201. The first planarization layer 251 and the second planarization layer 252 may include an organic insulating material.

Since the second planarization layer 252 is disposed on the first planarization layer 251 having a planarized surface, it can have a flat surface.

On the second planarization layer 252, the organic insulating structure 266 may be disposed. The organic insulating structure 266 may include the same organic insulating material as the bank 262 and the spacer 264 disposed on the active area AA.

On the organic insulating structure 266, the touch insulating structure 280 may be disposed. The touch insulating structure 280 may be a structure in which the touch buffer layer 277 and the touch interlayer insulating layer 282 that extend from the active area AA are in contact with each other in the up and down direction. For example, the touch insulating structure 280 may include multiple layers including an inorganic insulating material. For example, the touch insulating structure 280 may include silicon nitride (SiNx).

The touch insulating structure 280 may be disposed along the flat surfaces of the first link area LKA1, the bending area BDA, and the second link area LKA2. The touch insulating structure 280 may cover the inclined surfaces of the end portions of the organic insulating structure 266, the second planarization layer 252, and the first planarization layer 251 in the pad area PDA.

On the touch insulating structure 280, the second signal link wiring 287L may be disposed. The second signal link wiring 287L may be disposed with continuity on the flat touch insulating structure 280. Thereby, the second signal link wiring 287L can be formed at the same height in each of the first link area LKA1, the bending area BDA, and the second link area LKA2. For example, the second signal link wiring 287L may be located at the same height relative to the upper surface of the second planarization layer 252 in each of the first link area LKA1, the bending area BDA, and the second link area LKA2. That is, the distance (height) between the second signal link wiring 287L and the upper surface of the second planarization layer 252 may be uniform across the first link area LKA1, the bending area BDA, and the second link area LKA2. For example, the second signal link wiring 287L may be disposed in a single, continuous layer in the first link area LKA1, the bending area BDA, and the second link area LKA2.

The second signal link wiring 287L may extend to the pad area PDA to cover the third pad pattern 255p. A portion of the second signal link wiring 287L, which extends to the pad area PDA, may become the fourth pad pattern 287p of the pad PD in the pad area PDA.

Thereby, in the pad area PDA, the pad may be formed, in which the first pad pattern 223p, the second pad pattern 225p, the third pad pattern 255p, and the fourth pad pattern 287p are stacked from the lower side to the upper side.

On the second signal link wiring 287L, the first touch protective layer 290 may be disposed. The first touch protective layer 290 may include an organic insulating material. The first touch protective layer 290 may include an opening area OA exposing an area of the second signal link wiring 287L, which corresponds to the bending area BDA.

In the display device, the neutral plane may be located in the inside of the substrate 201. The neutral plane is a plane where compressive stress and tensile stress are offset from each other during the bending motion so that no stress occurs. With the closer distance to the neutral plane, the effect of stress may decrease. The first touch protective layer 290 may optimize the neutral plane by including the opening area OA disposed at a position corresponding to the bending area BDA.

According to another implementation of the present disclosure, the first planarization layer 251 disposed in the first link area LKA1 adjacent to the bending area BDA and in the second link area LKA2 adjacent to the pad area PDA may be disposed to have the same height without a step difference. Additionally, the second planarization layer 252 disposed on the first planarization layer 251 may also be disposed at the same height without a step difference on the first link area LKA1, the bending area BDA, and the second link area LKA2, because no step difference occurs in the first planarization layer 251 on the lower side of the second planarization layer 252. And, the organic insulating structure 266 disposed on the second planarization layer 252 may also be disposed at the same height without a step difference.

Thereby, the second signal link wiring 287L can be disposed along a flat surface while having no uneven underlying structure, so it is possible to prevent a crack defect caused by an irregular surface such as a step difference. That is, the second signal link wiring 287L may have a flat shape between the link area (i.e. LKA1 and LKA2) and the pad area BDA. Thus, it is possible to prevent a defect in which the second signal link wiring 287L is disconnected because of the crack defect, thereby decreasing the defect rate of the display device. Moreover, the decrease in the defect rate of the display apparatus will contribute to the reduction of production energy, which would be required to produce additional display apparatuses, thereby having the effect of abating greenhouse gas emissions.

Also, since the second signal link wiring 287L is disposed along a flat surface while having no uneven underlying structure, it is possible to prevent the second signal link wiring 287L in the first link area LKA1 or the second link area LKA2 adjacent to the bending area BDA from being damaged by stress generated when the bending area BDA undergoes the bending motion. Accordingly, there is an effect of being able to further reduce the bezel area visually perceived from the outside while reinforcing the robustness of the bending area BDA and the areas adjacent to the bending area.

Also, the second signal link wiring 287L may extend as a single wiring to the pad area PDA by way of the first link area LKA1, the bending area BDA, and the second link area LKA2. Thereby, in the third area TRA3 (see FIG. 3) of the second link area LKA2, the signal can be provided from the pad area PDA to the active area AA without using the contact areas CTA1, CTA2 (see FIG. 6) configured in multi-stage structures. Therefore, it is possible to prevent the occurrence of step differences, which would be generated when constructing the multi-stage structure, so the structure of the second signal link wiring 287L can become robust to cracks. Besides, since the second signal link wiring 287L extends as a single wiring to the pad area PDA by way of the first link area LKA1, the bending area BDA, and the second link area LKA2, it is possible to reduce the signal loss or noise generation, which would occur in the signal path including the first and second contact areas CTA1, CTA2 (see FIG. 6) configured in multi-stage structures.

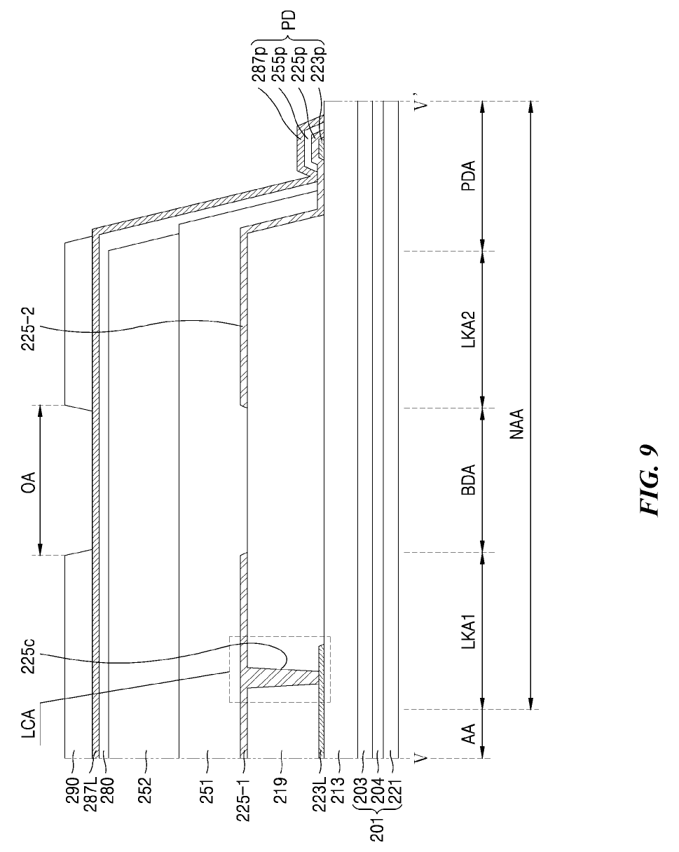

FIG. 9 is a drawing according to yet another implementation of the present disclosure. For example, FIG. 9 is a cross-sectional view taken along line V-V′ in FIG. 3. In FIG. 9, components identical to those of FIG. 8 may be denoted by the same reference signs. Thus, repetitive descriptions will be omitted or briefly made, and different features will be described.

Referring to FIG. 9, on the non-active area NAA of the substrate 201, the first insulating structure 213 may be disposed, which includes an inorganic insulating material. On the first insulating structure 213, the second insulating structure 219 may be disposed. The first link area LKA1 may include the first signal link wiring 223L disposed between the first insulating structure 213 and the second insulating structure 219.

On the second insulating structure 219, the first link contact electrode 225-1 and the second link contact electrode 225-2 may be disposed.

The first link contact electrode 225-1 may be electrically connected with the first signal link wiring 223L through the first via electrode 225c. The first signal link wiring 223L may be electrically connected with the first link contact electrode 225-1 through the first via electrode 255c in the link contact area LCA.

The second link contact electrode 225-2 disposed at another position spaced apart from the first link contact electrode 225-1 may extend to the pad area PDA, and a portion of the second link contact electrode 225-2 may form the second pad pattern 225p covering the first pad pattern 223p.

The first planarization layer 251 may cover the first link contact electrode 225-1 and the second link contact electrode 225-2. For example, the first planarization layer 251 may cover the second link contact electrode 225-2 extending along the inclined surface of the end portion of the second insulating structure 219 in the pad area PDA.

On the first planarization layer 251, the second planarization layer 252 may be disposed. Since the second planarization layer 252 is disposed on the first planarization layer 251 having a planarized surface, it can have a flat surface.

On the second planarization layer 252, the touch insulating structure 280 may be disposed. The touch insulating structure 280 may be a structure in which the touch buffer layer 277 and the touch interlayer insulating layer 282 that extend from the active area AA are in contact with each other in the up and down direction. For example, the touch insulating structure 280 may include multiple layers including an inorganic insulating material. For example, the touch insulating structure 280 may include silicon nitride (SiNx). The touch insulating structure 280 may cover the inclined surfaces of the end portions of the first planarization layer 251 and the second planarization layer 252 in the pad area PDA. The touch insulating structure 280 may be formed as a flat surface having no step difference.

On the touch insulating structure 280, the second signal link wiring 287L may be disposed. As the second signal link wiring 287L is disposed on the touch insulating structure 280 formed as a flat surface, it can be formed at the same height without a step difference in the first link area LKA1, the bending area BDA, and the second link area LKA2.

The second signal link wiring 287L may extend to the pad area PDA to cover the third pad pattern 255p. A portion of the second signal link wiring 287L, which extends to the pad area PDA, may become the fourth pad pattern 287p. For example, an end portion of the second signal link wiring 287L may overlap with the pad PD of the pad area PDA.

Thereby, in the pad area PDA, the pad may be formed, in which the first pad pattern 223p, the second pad pattern 225p, the third pad pattern 255p, and the fourth pad pattern 287p are stacked from the lower side to the upper side.

On the second signal link wiring 287L, the first touch protective layer 290 may be disposed, which includes an opening area OA. The opening area OA may be formed by removing a portion of the first touch protective layer 290 corresponding to the bending area BDA, so that the second signal link wiring 287L is exposed.

According to still another implementation of the present disclosure, as the second signal link wiring 287-2 is disposed on the first planarization layer 251, the second planarization layer 252, and the touch insulating structure 280, which have flat surfaces on the lower side of the second signal link wiring 287-2, it is possible to prevent that a crack occurs in the second signal link wiring 287-2 due to an uneven surface.

Additionally, the organic insulating structure may be omitted between the second planarization layer 252 and the touch insulating structure 280. Thereby, the thickness of the display apparatus can be reduced, so it is possible to prevent that the bending area BDA is damaged by stress during an operation of bending the bending area BDA.

The display apparatus according to various implementations of the present disclosure may be described as follows.

A display apparatus according to an implementation of the present disclosure may include a substrate including an active area and a non-active area disposed outside the active area, a link area, a bending area, and a pad area, which are located in the non-active area, a first signal link wiring disposed in the link area, an organic insulating layer disposed on the first signal link wiring, a touch insulating structure disposed on the organic insulating layer, a second signal link wiring extending to the pad area along a surface of the touch insulating structure, and a plurality of pads disposed on the pad area, wherein an end portion of the second signal link wiring may overlap with the pad.

According to various implementations of the present disclosure, the second signal link wiring may have a flat shape between the link area and the pad area.

According to various implementations of the present disclosure, the second signal link wiring may be located at a same height relative to the organic insulating layer in the link area and the bending area.

According to various implementations of the present disclosure, the active area may include: a plurality of transistors disposed on the substrate, each including a gate electrode, a source electrode, and a drain electrode; a pixel contact electrode disposed on the plurality of transistors; a light-emitting element electrically connected to the plurality of transistors through the pixel contact electrode, and including a first electrode, a light-emitting layer, and a second electrode; and a touch sensor unit located on the light-emitting element and including a plurality of touch electrodes.

According to various implementations of the present disclosure, the first signal link wiring may include a same material as the gate electrode, and may be formed in a same process as the gate electrode.

According to various implementations of the present disclosure, the second signal link wiring may include a same material as the touch electrode, and may be formed in a same process as the touch electrode.

According to various implementations of the present disclosure, the link area may include a first link area located in an area of the non-active area adjacent to the active area, and a second link area spaced apart from the first link area, and located in an area of the non-active area adjacent to the pad area, and the first signal link wiring may be disposed in the first link area.

According to various implementations of the present disclosure, the first link area may include a first link contact electrode overlapping with the first signal link wiring in an up and down direction, and the second link area may include a second link contact electrode disposed in a same layer as the first link contact electrode and having an end portion overlapping with the pad.

According to various implementations of the present disclosure, the display apparatus may further include a first touch protective layer disposed on the second signal link wiring, wherein the first touch protective layer may include an opening area exposing the second signal link wiring at a position corresponding to the bending area.

According to various implementations of the present disclosure, the organic insulating layer may include a first planarization layer covering the first signal link wiring, and a second planarization layer on the first planarization layer.

According to various implementations of the present disclosure, the organic insulating layer may further include a structure disposed between the second planarization layer and the touch insulating structure and including an organic insulating material.

According to various implementations of the present disclosure, the pad may include a first pad pattern including a same material as the first signal link wiring; a second pad pattern disposed on the first pad pattern and including a same material as the second link contact electrode; a third pad pattern on the second pad pattern; and a fourth pad pattern including a same material as the second signal link wiring.

According to various implementations of the present disclosure, the second signal link wiring may be disposed in a single, continuous layer in the first link area, the bending area, and the second link area.

According to various embodiments of the present disclosure, the first link contact electrode may be electrically connected with the first signal link wiring, and a connection wiring may extend from the first link area through the bending area to the second link area so as to connect the first link contact electrode and the second link contact electrode.

According to various embodiments of the present disclosure, the connection wiring may be formed from a same material as, and in a same process as, the pixel contact electrode.

While the implementations of the present disclosure have been described in detail with reference to the accompanying drawings, it should be understood by a person skilled in the art that the present disclosure is not necessarily limited to the above implementations, and the above implementations can be practiced in various modified forms without departing from the technical idea of the present disclosure. Accordingly, the implementations disclosed in the present disclosure are not intended to limit the technical idea of the present disclosure but to explain the technical idea of the present disclosure, and the scope of the technical idea of the present disclosure is not limited by these implementations. Therefore, it should be understood that the implementations described above are given only as an example in all respects but not for the purpose of limiting the disclosure.

What is claimed is:

1. A display apparatus comprising:
a substrate including an active area and a non-active area disposed outside the active area;
a link area, a bending area, and a pad area located in the non-active area;
a first signal link wiring disposed in the link area;
an organic insulating layer disposed on the first signal link wiring;
a touch insulating structure disposed on the organic insulating layer;
a second signal link wiring extending to the pad area along a surface of the touch insulating structure; and
a plurality of pads disposed on the pad area,
wherein an end portion of the second signal link wiring overlaps the pad.

2. The display apparatus of claim 1, wherein the second signal link wiring has a flat shape between the link area and the pad area.

3. The display apparatus of claim 1, wherein the second signal link wiring is located at a same height relative to the organic insulating layer in the link area and the bending area.

4. The display apparatus of claim 1, wherein the active area includes:
a plurality of transistors disposed on the substrate, each transistor including a gate electrode, a source electrode, and a drain electrode;
a pixel contact electrode disposed on the plurality of transistors;
a light-emitting element electrically connected to the plurality of transistors through the pixel contact electrode, the light-emitting element including a first electrode, a light-emitting layer, and a second electrode; and
a touch sensor unit located on the light-emitting element, the touch sensor unit including a plurality of touch electrodes.

5. The display apparatus of claim 4, wherein the first signal link wiring includes a same material as the gate electrode, and wherein the first signal link wiring is formed in a same process as the gate electrode.

6. The display apparatus of claim 4, wherein the second signal link wiring includes a same material as the touch electrode, and wherein the second signal link wiring is formed in a same process as the touch electrode.

7. The display apparatus of claim 4, wherein the link area includes:
a first link area located in an area of the non-active area adjacent to the active area; and
a second link area spaced apart from the first link area, and located in an area of the non-active area adjacent to the pad area, and
wherein the first signal link wiring is disposed in the first link area.

8. The display apparatus of claim 7, wherein:
the first link area includes a first link contact electrode overlapping the first signal link wiring in an up and down direction, and
wherein the second link area includes a second link contact electrode disposed in a same layer as the first link contact electrode, the second link contact electrode having an end portion overlapping the pad.

9. The display apparatus of claim 1, further comprising:
a first touch protective layer disposed on the second signal link wiring,
wherein the first touch protective layer includes an opening area exposing the second signal link wiring at a position corresponding to the bending area.

10. The display apparatus of claim 1, wherein the organic insulating layer includes:
a first planarization layer covering the first signal link wiring; and
a second planarization layer on the first planarization layer.

11. The display apparatus of claim 10, wherein the organic insulating layer further includes a structure disposed between the second planarization layer and the touch insulating structure, the structure including an organic insulating material.

12. The display apparatus of claim 8, wherein the pad includes:
a first pad pattern including a same material as the first signal link wiring;
a second pad pattern disposed on the first pad pattern, the second pad pattern including a same material as the second link contact electrode;
a third pad pattern on the second pad pattern; and
a fourth pad pattern including a same material as the second signal link wiring.

13. The display apparatus of claim 7, wherein the second signal link wiring is disposed in a single, continuous layer in the first link area, the bending area, and the second link area.

14. The display apparatus of claim 8, wherein the first link contact electrode is electrically connected with the first signal link wiring, and
wherein a connection wiring extends from the first link area through the bending area to the second link area so as to connect the first link contact electrode and the second link contact electrode.

15. The display apparatus of claim 14, wherein the connection wiring is formed from a same material as, and in a same process as, the pixel contact electrode.
